(19) United States
(12) Patent Application Publication
(10) Pub. No.: US 2026/0290462 A1
(43) Pub. Date: Sep. 24, 2026

(54) MEMORY SYSTEM AND METHOD OF CONTROLLING MEMORY SYSTEM

(71) Applicant: Kioxia Corporation, Tokyo (JP)

(72) Inventor: Hiroki KOBAYASHI, Kamakura (JP)

(73) Assignee: Kioxia Corporation, Tokyo (JP)

(21) Appl. No.: 19/240,450

(22) Filed: Jun. 17, 2025

(30) Foreign Application Priority Data
Mar. 24, 2025 (JP) 2025-048683

(51) Int. Cl. G11C 16/14; G11C 29/12

(52) U.S. Cl. CPC G11C 16/14; G11C 29/12005; G11C 2029/1202

(57) ABSTRACT

A memory system according to one embodiment includes memory devices, and a memory controller. The memory controller is configured to: receive a data write command to any of the memory devices from an external host device; and change a power throttling setting based on information on a write destination designated by the received write command. As a result of changing the power throttling setting, in a case where a write energy at the write destination is a first value, the number of write operations that can be executed in parallel is a first number, and in a case where the write energy at the write destination is a second value lower than the first value, the number of write operations that can be executed in parallel is a second number larger than the first number.

### CROSS-REFERENCE TO RELATED APPLICATIONS

This application is based upon and claims the benefit of priority from Japanese Patent Application No. 2025-048683, filed Mar. 24, 2025, the entire contents of which are incorporated herein by reference.

### FIELD

Embodiments described herein relate generally to a memory system and a method of controlling the memory system.

### BACKGROUND

A NAND flash memory (Hereinafter, also referred to as a flash memory) capable of storing data in a nonvolatile manner is known. In addition, a memory system including a plurality of flash memories is also known. The memory system temporarily stores data related to writing of data to the flash memory in a volatile memory. The data stored in the volatile memory may be lost in a case where a power supplied to the memory system stops without notice or in a case where a voltage value thereof decreases. To address this, a power loss protection (PLP) function is known as a function for avoiding the loss of data stored in the volatile memory. The PLP function is a function of storing data stored in the volatile memory in the flash memory by using electric energy stored in a power storage device such as a capacitor while a power supply to be supplied is stopped or a voltage value thereof is lowered.

In the memory system, a power throttling design according to a write time of a memory device is implemented to implement the PLP function. In an example of the power throttling design, the number of flash memories capable of executing write operations in parallel is designed. For example, the number of flash memories capable of executing the write operation in parallel is designed based on a write time (write energy) required for the write operation of the flash memory and a storage capacity of the power storage device. On the other hand, the write time varies in the flash memory. Therefore, the power throttling design in consideration of a case where the write time is required the most can be a factor of suppressing the improvement in the performance of the memory system.

### BRIEF DESCRIPTION OF DRAWINGS

FIG. 1 is a block diagram illustrating an example of a hardware configuration of a memory system according to a first embodiment.

FIG. 2 is a block diagram illustrating an example of a hardware configuration of a memory controller included in the memory system according to the first embodiment.

FIG. 3 is a block diagram illustrating an example of a hardware configuration of a memory device included in the memory system according to the first embodiment.

FIG. 4 is a circuit diagram illustrating an example of a circuit configuration of a memory cell array included in the memory device according to the first embodiment.

FIG. 5 is a block diagram illustrating an example of a functional configuration of the memory controller according to the first embodiment.

FIG. 6 is a graph illustrating an example of word line dependency of a write time included in the memory controller according to the first embodiment.

FIG. 7 is a diagram illustrating an example of a word line group management table included in the memory controller according to the first embodiment.

FIG. 8 is a diagram illustrating an example of a word line group—weight conversion table included in the memory controller according to the first embodiment.

FIG. 9 is a flowchart illustrating an example of an operation of the memory controller according to the first embodiment.

FIG. 10 is a block diagram illustrating an example of a functional configuration of a memory controller according to a second embodiment.

FIG. 11 is a diagram illustrating an example of a write/erase count—weight conversion table included in the memory controller according to the second embodiment.

FIG. 12 is a flowchart illustrating an example of an operation of the memory controller according to the second embodiment.

FIG. 13 is a block diagram illustrating an example of a functional configuration of a memory controller according to a third embodiment.

FIG. 14 is a diagram illustrating an example of a temperature—weight conversion table included in the memory controller according to the third embodiment.

FIG. 15 is a flowchart illustrating an example of an operation of the memory controller according to the third embodiment.

FIG. 16 is a block diagram illustrating an example of a functional configuration of a memory controller according to a fourth embodiment.

FIG. 17 is a diagram illustrating an example of a write time category management table included in the memory controller according to the fourth embodiment.

FIG. 18 is a diagram illustrating an example of a write time category—weight conversion table included in the memory controller according to the fourth embodiment.

FIG. 19 is a diagram illustrating an example of a write time—write time category conversion table included in the memory controller according to the fourth embodiment.

FIG. 20 is a flowchart illustrating an example of an operation of the memory controller according to the fourth embodiment.

### DETAILED DESCRIPTION

In general, according to one embodiment, a memory system includes memory devices, and a memory controller. The memory controller controls the memory devices. The memory controller is configured to: receive a data write command to any of the memory devices from an external host device; and change a power throttling setting based on information on a write destination designated by the received write command. As a result of changing the power throttling setting, in a case where a write energy at the write destination is a first value, the number of write operations that can be executed in parallel is a first number, and in a case where the write energy at the write destination is a second value lower than the first value, the number of write operations that can be executed in parallel is a second number larger than the first number.

Hereinafter, embodiments will be described with reference to the drawings. Each embodiment exemplifies a device and a method for embodying the technical idea of the invention. The drawings are schematic or conceptual. The illustration of the configuration is omitted as appropriate. Components having substantially the same functions and configurations are denoted by the same reference numerals. Characters, numbers, and the like added to reference numerals are referred to by the same reference numerals, and are used to distinguish between similar elements.

### <1> First Embodiment

A memory system 1 according to a first embodiment is configured to change a weight (credit) of a command used in a power throttling setting based on a position of a word line WL as a write destination. Hereinafter, details of the memory system 1 according to the first embodiment will be described.

### <1-1> Configuration

First, a configuration of the memory system 1 according to the first embodiment will be described.

### <1-1-1> Hardware Configuration of Memory System 1

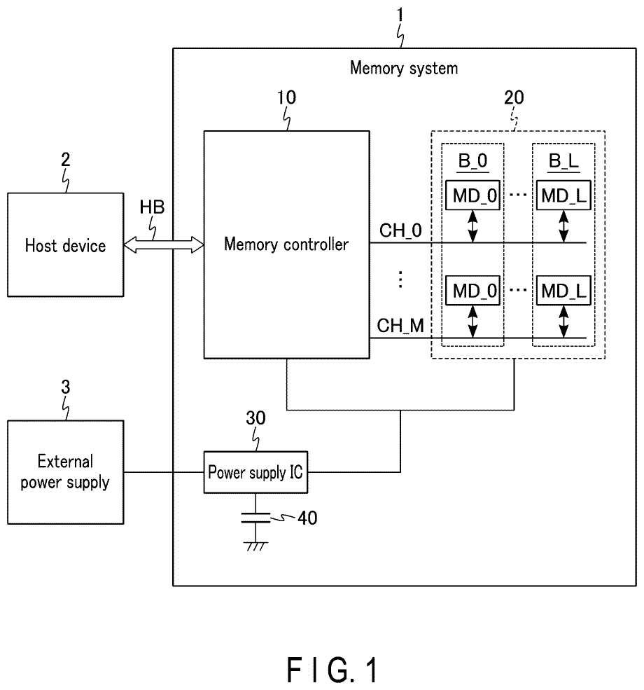

FIG. 1 is a block diagram illustrating an example of a hardware configuration of the memory system 1 according to the first embodiment. As illustrated in FIG. 1, the memory system 1 can be connected to an external host device 2 and an external power supply 3. The memory system 1 is a storage device such as a memory card, a solid state drive (SSD) or a universal flash storage (UFS) device, and has a PLP function. The host device 2 is an electronic device such as a personal computer, a personal digital assistant, or a server. The host device 2 may be simply referred to as a “host”. The external power supply 3 is a power supply source for the memory system 1. The external power supply 3 can be included in the host device 2.

The memory system 1 includes, for example, a memory controller 10, a flash memory set 20, a power supply integrated circuit (IC) 30, and a power storage device 40. The memory controller 10 is connected to the flash memory set 20 via a plurality of channels CH_0 to CH_M (M is an integer of 1 or more). The flash memory set 20 includes a plurality of memory devices MD_0 to MD_L (L is an integer of 1 or more) for each channel CH. That is, a plurality of memory devices MD_0_MD_L is connected to each channel CH. A set of memory devices MD to which the same chip address is allocated among the plurality of channels CH is referred to as, for example, a bank B. In this example, the flash memory set 20 includes a plurality of banks B_0 to B_L respectively associated with the memory devices MD_0 to MD_L.

The memory controller 10 is, for example, a semiconductor integrated circuit configured as a system on a chip (SoC), an application specific integrated circuit (ASIC), or a field-programmable gate array (FPGA). The memory controller 10 has a function of managing and controlling the plurality of memory devices MD included in the flash memory set 20. The memory controller 10 is connected to the host device 2 through a host bus HB. The memory controller 10 can control the memory device MD to be operated, for example, by transmitting a command or the like to the memory device MD to be operated via the corresponding channel CH based on a command received from the host device 2. In the present specification, data instructed to be written by the host device 2 is referred to as “write data”. Data read from the memory device MD is referred to as “read data”.

The memory device MD is a semiconductor memory device configured to store data in a nonvolatile manner. The memory device MD corresponds to one chip of the semiconductor memory device. Furthermore, the memory device MD corresponds to, for example, a NAND flash memory (hereinafter, also referred to as a flash memory). In a flash memory, a unit of a data read operation and a data write operation is called a page. The memory device MD includes, for example, a plurality of memory cell transistors MT, a plurality of bit lines BL, and a plurality of word lines WL (not illustrated in FIG. 1). Each memory cell transistor MT is associated with one bit line BL and one word line WL. A column address is allocated to each bit line BL. A page address is allocated to each word line WL. The configuration of the memory device MD will be described later.

The power supply IC 30 generates power for driving a plurality of electric circuit components included in the memory system 1 based on a power supplied from the external power supply 3. The plurality of electric circuit components includes a memory controller 10 and a flash memory set 20. Then, the power supply IC 30 supplies the generated power to each of the electric circuit components. The power supply IC 30 may be referred to as a power supply circuit. For example, the power supply IC 30 generates, as power, a plurality of different voltages to be power supply voltages of the plurality of electric circuit components. The power supply IC 30 may generate power for driving other electric circuit components (not illustrated).

The power storage device 40 can store electric energy. The power storage device 40 is, for example, a chargeable capacitor or battery. The power storage device 40 is charged by the power supply IC 30 in a case where power is normally supplied from the external power supply 3 to the memory system 1. In a case where the power storage device 40 is a capacitor, any capacitor can be used. For example, as the power storage device 40, an electrolytic capacitor, a tantalum capacitor, a multilayer ceramic capacitor, or an electrical double-layer capacitor can be adopted.

In the PLP function of the memory system 1, in a case where the power supply from the external power supply 3 is stopped, the power supply IC 30 switches the power supply source to the plurality of electric circuit components included in the memory system 1 from the external power supply 3 to the power storage device 40. As a result, the electric energy stored in the power storage device 40 is supplied to at least each of the memory controller 10 and the flash memory set 20 via the power supply IC 30. Therefore, even after the power supply from the external power supply 3 is stopped, each of the memory controller 10 and the flash memory set 20 can be operated by the electric energy stored in the power storage device 40 for a while. At this time, the memory controller 10 executes a PLP operation using the electric energy stored in the power storage device 40. In the PLP operation, the memory controller 10 causes the memory device MD to save (store) data stored in a volatile memory to be described later.

Note that the power supply IC 30 may monitor the voltage supplied from the external power supply 3 in order to detect that the power supply from the external power supply 3 is stopped. For example, in a case where the voltage supplied from the external power supply 3 falls below a predetermined level, the power supply IC 30 determines that power-off has occurred, and transmits a power-off signal to the memory controller 10. Then, the power supply IC 30 switches the power supply source from the external power supply 3 to the power storage device 40, and the memory controller 10 starts the PLP operation.

Note that the power supply IC 30 may not be configured to detect the power-off. For example, the memory controller 10 may detect the power-off. The stop of the power supply from the external power supply 3 may be notified the memory system 1 by the host device 2. In a case of receiving the notice of the stop of the power supply from the external power supply 3, the memory controller 10 can execute a shutdown operation of the memory system 1 including processing similar to the PLP operation according to the notice content.

### 1: Hardware Configuration of Memory Controller 10

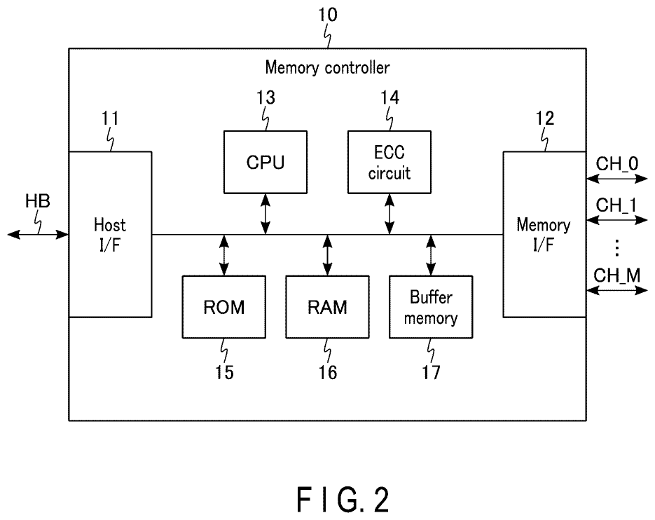

FIG. 2 is a block diagram illustrating an example of a hardware configuration of the memory controller 10 included in the memory system 1 according to the first embodiment. As illustrated in FIG. 2, the memory controller 10 includes, for example, a host interface (host I/F) 11, a memory interface (memory I/F) 12, a central processing unit (CPU) 13, an error correction code (ECC) circuit 14, a read only memory (ROM) 15, a random access memory (RAM) 16, and a buffer memory 17. The host interface 11, the memory interface 12, the CPU 13, the ECC circuit 14, the ROM 15, the RAM 16, and the buffer memory 17 may be connected to an internal bus.

The host interface 11 controls communication between the host device 2 and the memory controller 10 according to an interface standard. The host interface 11 is connected to the host device 2 through a host bus HB. The host interface 11 may support interface standards such as PCI Express (PCIe™), Non-Volatile Memory Express™ (NVMe™), Serial Attached SCSI (SAS), Serial Advanced Technology Attachment (SATA), Universal Flash Storage (UFS) (M-PHY), and embedded Multi Media Card (eMMC).

The memory interface 12 controls communication according to the interface standard between the memory controller 10 and each memory device MD of the flash memory set 20. A plurality of channels CH_0 to CH_M is connected to the memory interface 12. For example, the memory interface 12 can transmit a command or the like in parallel for one memory device MD for each channel CH using a plurality of channels CH. Note that commands and the like for each of the plurality of memory devices MD sharing the channel CH are serially transmitted. The memory interface 12 may support interface standards such as Toggle DDR and Open NAND Flash Interface (ONFI).

The CPU 13 controls an entire operation of the memory controller 10 based on a program such as firmware. For example, the CPU 13 instructs the memory device MD via the memory interface 12 to perform a data write operation in accordance with a write command received via the host interface 11. In accordance with a read command received via the host interface 11, the CPU 13 instructs the memory device MD via the memory interface 12 to perform a data read operation. For example, the CPU 13 is a processor capable of executing a program for controlling the memory controller 10.

The ECC circuit 14 executes processing related to data error correction. For example, the ECC circuit 14 generates a parity for each certain unit of write data received from the host device 2 in the write operation. The generated parity is added to the write data and written to the memory device MD. In the read operation, the ECC circuit 14 generates a syndrome based on read data (a set of data and parity) received from the memory device MD. Then, the ECC circuit 14 detects an error in the read data based on the generated syndrome and corrects the detected error.

The ROM 15 stores, for example, a program such as firmware. As the ROM 15, for example, a nonvolatile memory such as an Electrically Erasable Programmable Read-Only Memory (EEPROM™) is used. The CPU 13 executes various processing by executing firmware stored in the ROM 15 or the like.

The RAM 16 is a memory device used as a work area of the CPU 13. The RAM 16 stores, for example, a lookup table (LUT) for managing a storage area of the memory device MD. The LUT includes, for example, information in which a logical address (logical page) of a data storage destination is associated with a physical address. The LUT is appropriately rewritten according to the operation of the memory system 1. The LUT is read from the memory device MD at the time of powering on the memory system 1. The LUT is stored in the memory device MD at the time of powering off the memory system 1. The CPU 13 may generate a difference of the LUT and appropriately back up the difference in the memory device MD. The RAM 16 is an example of a volatile memory. As the RAM 16, for example, a dynamic random access memory (DRAM), a static random access memory (SRAM), or the like is used. The RAM 16 may be provided outside the memory controller 10.

The buffer memory 17 is a storage device used as a temporary storage area of data. The buffer memory 17 temporarily stores, for example, write data received from the host device 2, read data received from the memory device MD, and the like. The buffer memory 17 is an example of a volatile memory. As the buffer memory 17, for example, a DRAM, an SRAM, or the like is used. The buffer memory 17 may be provided outside the memory controller 10.

### 2: Hardware Configuration of Memory Device MD

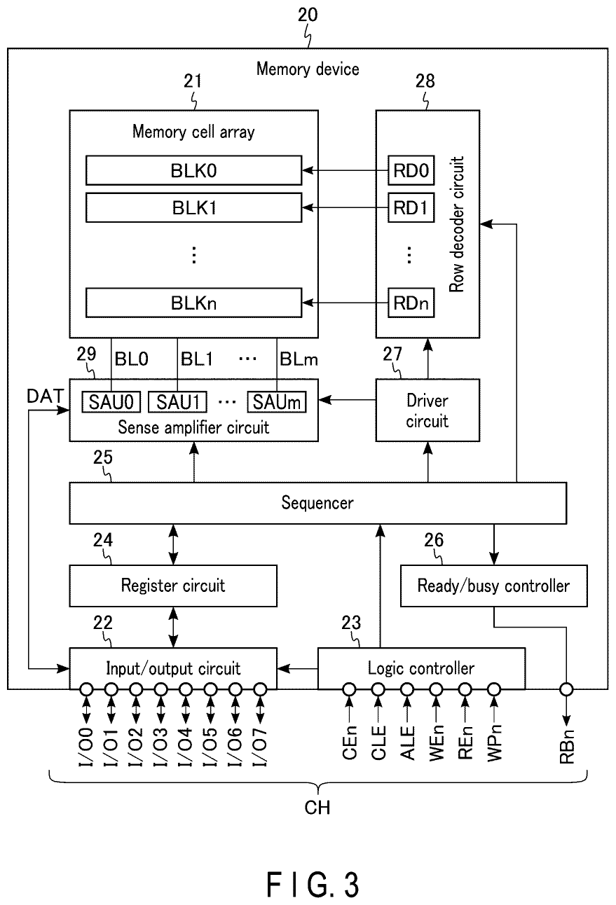

FIG. 3 is a block diagram illustrating an example of a hardware configuration of the memory device MD included in the memory system 1 according to the first embodiment. As illustrated in FIG. 3, the memory device MD includes, for example, a memory cell array 21, an input/output circuit 22, a logic controller 23, a register circuit 24, a sequencer 25, a ready/busy controller 26, a driver circuit 27, a row decoder circuit 28, and a sense amplifier circuit 29. The signals transmitted and received via the channel CH include, for example, input/output signals I/O0 to I/O7, control signals CEn, CLE, ALE, WEn, REn, and WPn, and a ready/busy signal RBn.

The memory cell array 21 is a set of a plurality of memory cell transistors MT (not illustrated in FIG. 3). The memory cell array 21 includes a plurality of blocks BLK0 to BLKn (n is an integer of 1 or more). The block BLK is used, for example, as a unit of data erase operation. A block address is allocated to each block BLK. In the memory cell array 21, a plurality of bit lines BL0 to BLm (m is an integer of 1 or more) and a plurality of word lines WL (not illustrated in FIG. 3) are provided. Note that the block BLK may be divided into sub-blocks and managed.

The input/output circuit 22 controls transmission and reception (input/output) of the input/output signals I/O0 to I/O7. The input/output signal I/O includes data DAT, status information, an address, a command, and the like. The input/output circuit 22 can input and output the data DAT between the sense amplifier circuit 29 and the memory controller 10. The input/output circuit 22 can output the status information transferred from the register circuit 24 to the memory controller 10. The input/output circuit 22 can output each of the address and the command transferred from the memory controller 10 to the register circuit 24.

The logic controller 23 controls the input/output circuit 22 and the sequencer 25 based on various control signals input from the memory controller 10. For example, the logic controller 23 enables the memory device MD based on the control signal CEn. The logic controller 23 notifies the input/output circuit 22 that the input/output signal I/O received by the memory device MD is a command and an address based on the control signals CLE and ALE. The logic controller 23 orders the input/output circuit 22 to receive the input/output signal I/O based on the control signal WEn, and orders the input/output circuit 22 to transmit the input/output signal I/O based on the control signal REn. The logic controller 23 puts the memory device MD into a protected state based on the control signal WPn.

The register circuit 24 temporarily stores a status, an address, a command, and the like. The status is information indicating an operation state of the memory device MD. The status is updated based on the control of the sequencer 25 and transferred to the memory controller 10 through the input/output circuit 22. The address may include a block address, a page address, a column address, and the like. The commands include commands regarding various operations of the memory device MD.

The sequencer 25 controls the entire operation of the memory device MD. The sequencer 25 executes a read operation, a write operation, an erase operation, and the like based on the command and the address stored in the register circuit 24.

The ready/busy controller 26 generates the ready/busy signal RBn under the control of the sequencer 25. The ready/busy signal RBn notifies the memory controller 10 whether the memory device MD is in a ready state or a busy state. The ready state is a state in which the memory device MD can receive a command from the memory controller 10. The busy state is a state in which the memory device MD cannot accept (or does not process even if accepting) a command from the memory controller 10.

The driver circuit 27 generates a voltage used in a read operation, a write operation, an erase operation, and the like. The driver circuit 27 supplies the generated voltage to the row decoder circuit 28, the sense amplifier circuit 29, and the like.

The row decoder circuit 28 is a circuit used for selecting the block BLK and supplying a voltage to wiring such as the word line WL. The row decoder circuit 28 includes a plurality of row decoders RD0 to RDn. The row decoders RD0 to RDn are associated with the blocks BLK0 to BLKn, respectively. Each row decoder RD can set the associated block BLK to be selected or non-selected based on the block address.

The sense amplifier circuit 29 is a circuit used for supplying a voltage to each bit line BL and reading data. The sense amplifier circuit 29 includes a plurality of sense amplifier units SAU0 to SAUm. The sense amplifier units SAU0 to SAUm are associated with a plurality of bit lines BL0 to BLm, respectively. Each sense amplifier unit SAU can determine data read from the selected memory cell transistor MT based on the voltage of the associated bit line BL.

In the memory device MD, a set of the memory cell array 21, the row decoder circuit 28, and the sense amplifier circuit 29 may be referred to as a plane. The plane includes at least the memory cell array 21. The memory device MD may include a plurality of planes. The sequencer 25 can be configured to be able to control each of the plurality of planes. The memory device MD may be configured to be operable independently for each plane.

### <1-1-2> Circuit Configuration of Memory Cell Array 21

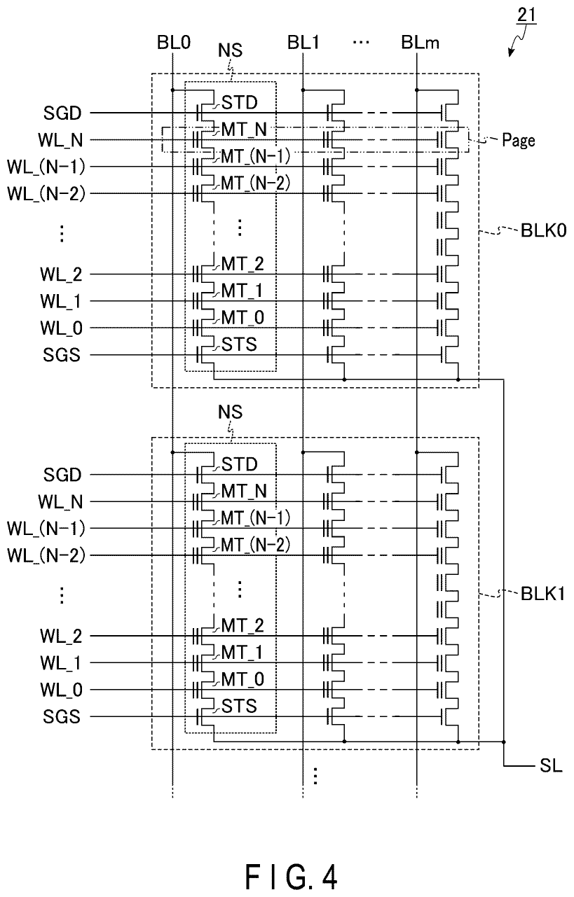

FIG. 4 is a circuit diagram illustrating an example of a circuit configuration of the memory cell array 21 included in the memory device MD according to the first embodiment. FIG. 4 illustrates two blocks BLK0 and BLK1 among the plurality of blocks BLK included in the memory cell array 21. As illustrated in FIG. 4, in the memory cell array 21, a plurality of word lines WL_0 to WL_N (N is an integer of 1 or more) and select gate lines SGD and SGS are provided for each block BLK. The plurality of bit lines BL0 to BLm and a source line SL are shared by a plurality of blocks BLK, for example.

Each block BLK includes a plurality of NAND strings NS. The plurality of NAND strings NS is associated with the bit lines BL0 to BLm. Each NAND string NS is connected between the associated bit line BL and source line SL. Each NAND string NS includes, for example, a plurality of memory cell transistors MT_0 to MT_N and select transistors STD and STS. Each memory cell transistor MT has a control gate and a charge storage film, and stores data in a nonvolatile manner. Each of the select transistors STD and STS is used to select the block BLK.

In each NAND string NS, the select transistor STD, the memory cell transistors MT_N to MT_0, and the select transistor STS are connected in series in this order. Specifically, a drain end and a source end of the select transistor STD are connected to the associated bit line BL and a drain end of the memory cell transistor MT_N, respectively. In the memory cell transistors MT_N to MT0 connected in series, a source end of one of the two adjacent memory cell transistors MT and a drain end of the other memory cell transistor MT are connected. A drain end and a source end of the select transistor STS are connected to a source end of the memory cell transistor MT_0 and the source line SL, respectively.

In each block BLK, a select gate line SGD is connected to a gate end of the select transistor STD of each NAND string NS. In each block BLK, the select gate line SGS is connected to a gate end of the select transistor STS of each NAND string NS. In each block BLK, the plurality of word lines WL_0 to WL_N is connected to control gate ends of the plurality of memory cell transistors MT_0 to MT_N of each NAND string NS, respectively.

The memory cell array 21 may have another circuit configuration. For example, a plurality of independently controllable select gate lines SGD may be provided for each block BLK. In this case, each block BLK is configured to be selectable (controllable) in a plurality of units associated with the plurality of select gate lines SGD.

### <1-1-3> Functional Configuration of Memory Controller 10

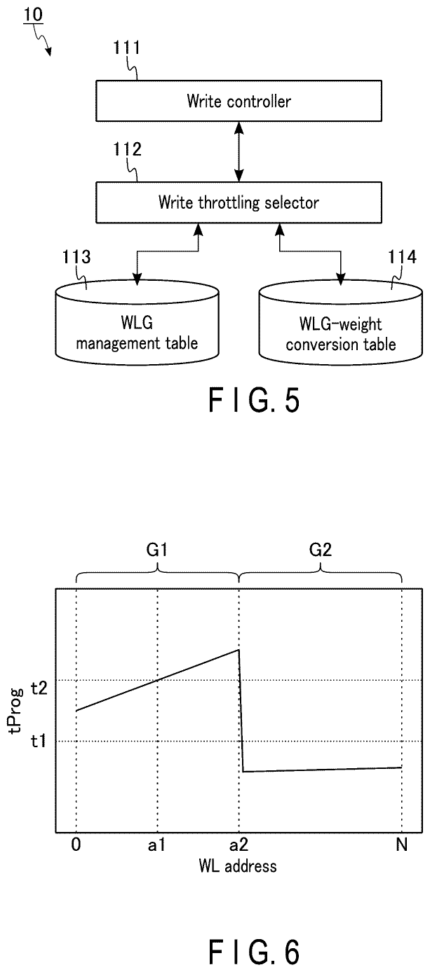

FIG. 5 is a block diagram illustrating an example of a functional configuration of the memory controller 10 according to the first embodiment. As illustrated in FIG. 5, the memory controller 10 includes, for example, a write control unit 111, a write throttling selector 112, a word line group (WLG) management table 113, and a word line group (WLG)—weight (credit) conversion table 114.

The write control unit 111 is a functional block that executes processing related to the write operation. In a case where the memory controller 10 receives a write command and write data from the host device 2, the write control unit 111 executes processing related to a write operation and power throttling setting in the write operation. For example, in the power throttling setting, the write control unit 111 inquires of the write throttling selector 112 about the weight setting corresponding to the write command to be executed. Then, the write control unit 111 reserves execution of the write operation using the weight setting received from the write throttling selector 112. As described above, the write control unit 111 can apply different weight settings for each received write command. Then, the write control unit 111 starts the reserved write operation at an appropriate timing according to the total weight of a command being executed.

The write throttling selector 112 is a functional block that manages the weight setting set for each word line WL, and can obtain an appropriate power throttling setting according to the word line WL of a write destination. For example, upon receiving an inquiry from the write control unit 111, the write throttling selector 112 first acquires information on the word line group WLG to which the word line WL to be operated belongs using the WLG management table 113. The word line group WLG is a set of a plurality of word lines WL to which the same weight setting is allocated. The WLG management table 113 is data defining which word line group WLG each word line WL belongs to. Then, the write throttling selector 112 acquires the weight setting corresponding to the acquired information on the word line group WLG using the WLG—weight conversion table 114. The WLG—weight conversion table 114 is data that defines the power throttling setting for each word line group WLG. Thereafter, the write throttling selector 112 transfers the acquired weight setting to the write control unit 111.

In the present specification, the “write destination word line WL” indicates the word line WL connected to the write target memory cell transistor MT. In the present specification, the “weight (weight setting)” is a numerical value associated with commands of various operations received by the memory system 1 from the host device 2, and corresponds to a power throttling setting. The weight of the command is used to manage the number of chips (the number of memory devices MD) capable of executing the write operation in parallel in the memory system 1. In the memory system 1, the maximum value (allowable value) of the sum of the weights of the commands executable in parallel is set in advance. Then, the memory controller 10 executes the command received from the host device 2 in such a way that the sum of the weights of the commands corresponding to the currently executed operation does not exceed a maximum value. The weight of the command is based on an electric energy used in the operation of the memory system 1. That is, the maximum value of the sum of the weights of the commands that can be executed in parallel is based on the maximum amount of electric energy that can be simultaneously used by the memory system 1.

Hereinafter, the electric energy used in the write operation is referred to as “write energy”. The write energy is defined by, for example, “voltage×current×time [J]”. This “time” corresponds to a time (hereinafter, also referred to as a write time tProg) from a start time to an end time of the write operation. The write energy may be defined by the number of sets of a program operation and a verify read operation executed in the write operation. The program operation includes an operation of applying a high voltage (program voltage) capable of injecting electrons into the charge storage film of the memory cell transistor MT to the word line WL connected to the write target memory cell transistor MT. The verify read operation is a read operation for confirming whether the threshold voltage of the memory cell transistor MT to be written has reached a desired voltage. In addition, the write energy may be estimated from a value of a maximum program voltage used in the write operation, or may be estimated from the write time tProg.

### 1: Configuration of Word Line Group Management Table 113

The WLG management table 113 is created based on the word line WL dependency of the write time tProg. FIG. 6 is a graph illustrating an example of word line dependency of the write time tProg included in the memory controller 10 according to the first embodiment. In the graph illustrated in FIG. 6, the horizontal axis represents the WL address, and the vertical axis represents the write time tProg. The write time tProg corresponds to the write energy. In this example, the WL address is associated with, for example, a numeral (number) allocated to an end of the word line WL described with reference to FIG. 4. In addition, this example corresponds to a case where a hole process (etching process) for forming a structure corresponding to the plurality of memory cell transistors MT of each NAND string NS is divided into two times. The plurality of word lines WL_0 to WL_N is classified into groups G1 and G2 corresponding to processes divided twice. The group G1 includes a plurality of word lines WL arranged on the source line SL side among the plurality of word lines WL. The group G2 includes a plurality of word lines WL arranged on the bit line BL side among the plurality of word lines WL.

As illustrated in FIG. 6, a tendency of the write time tProg may vary depending on the number of the word line WL. Furthermore, the tendency of the write time tProg may be greatly different between the groups G1 and G2, and may be different depending on the position of the word line WL even in the same group G. This is because the characteristics of the memory cell transistor MT are different according to the number of the word line WL due to a difference in the structure of the memory cell transistor. Then, the word line group WLG is classified according to the length of the write time tProg. In this example, a threshold t1 of the write time tProg and a threshold t2 longer than the threshold t1 are used for classification of the word line group WLG. Word lines WL_a1 and WL_a2 are associated with the thresholds t1 and t2, respectively. The word line WL_a1 is associated with the word line WL arranged in an intermediate portion among the plurality of word lines WL of the group G1. The word line WL_a2 is associated with the word line WL adjacent to the word line WL of the group G2 among the plurality of word lines WL of the group G1.

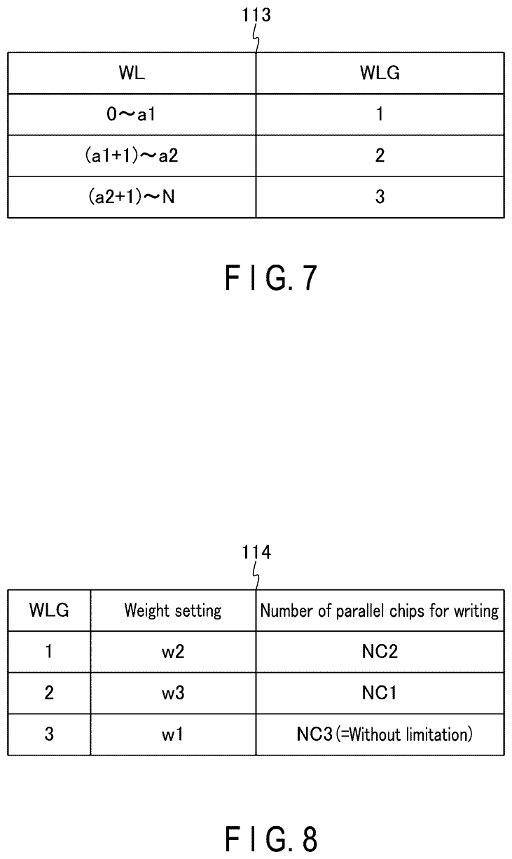

FIG. 7 is a diagram illustrating an example of a word line group (WLG) management table 113 included in the memory controller 10 according to the first embodiment. As illustrated in FIG. 7, the WLG management table 113 stores information associating the address (WL address) of the word line WL with the word line group WLG. In this example, the word lines WL_0 to WL_a1 are associated with the word line group WLG1. Word lines WL_ (a1+1) to WL_a2 are associated with a word line group WLG2. Word lines WL_ (a2+1) to WL_N are associated with a word line group WLG3. In the memory system 1 according to the first embodiment, the word line groups WLG may be classified into two types or four or more types.

### 2: Configuration of Word Line Group—Weight Conversion Table 114

FIG. 8 is a diagram illustrating an example of a word line group (WLG)—weight (credit) conversion table 114 included in the memory controller 10 according to the first embodiment. As illustrated in FIG. 8, the WLG—weight conversion table 114 stores information in which the word line group WLG and the weight setting are associated with each other. Note that the weight setting corresponds to a numerical value of the weight of the command. In the example shown in FIG. 8, the number of write parallel chips is also shown as the number of parallel chips for writing. The number of write parallel chips indicates the maximum number of memory devices MD (chips of the flash memory) that can execute the write operation in parallel in a case where only the associated weight setting is applied.

In this example, weight settings w2, w3, and w1 are associated with the word line groups WLG1, WLG2, and WLG3, respectively. The magnitude relationship of the weight setting is w1<w2<w3. In addition, the numbers of write parallel chips of the word line groups WLG1, WLG2, and WLG3 are NC2, NC1, and NC3, respectively. A relationship of the number of write parallel chips is NC1<NC2<NC3. That is, in a case where the write operation with the smallest weight setting w1 is executed in parallel, the number of write parallel chips becomes the largest. In this example, in a case of receiving only the write command with the weight setting w1, the memory controller 10 can execute the write operation in parallel substantially without limitation (however, with the number of channels CH as an upper limit). The ability to execute write operations in unrestricted parallel means that no power throttling occurs. On the other hand, in a case where the memory controller 10 receives only the write command with the weight settings w2 or w3, the power throttling may occur. Therefore, the number of write parallel chips in the case where the memory controller 10 receives only the write command with the weight setting w2 or w3 is smaller than that in the case of receiving only the write command with the weight setting w1.

### <1-2> Operation

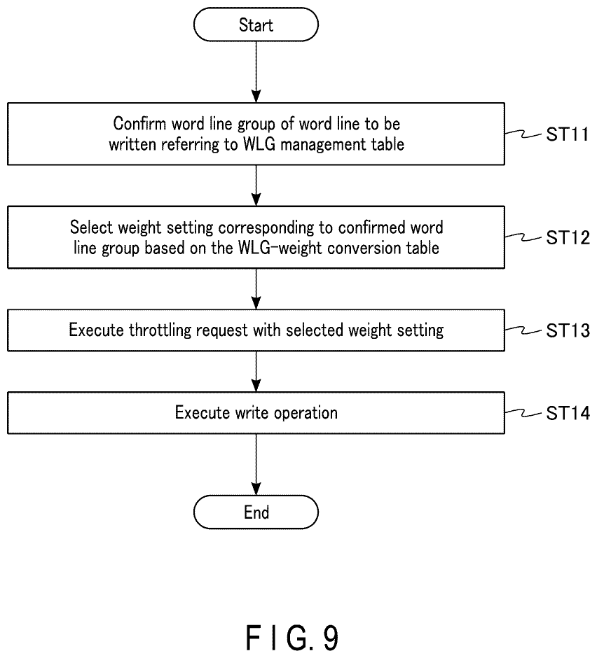

Next, the operation of the memory controller 10 in the write operation of the memory system 1 according to the first embodiment will be described with reference to FIG. 9. FIG. 9 is a flowchart illustrating an example of the operation of the memory controller 10 according to the first embodiment. In a case of receiving a write command and write data from the host device 2, the memory controller 10 starts a series of processing in FIG. 9 (start).

First, the memory controller 10 refers to the WLG management table 113 to confirm the word line group WLG of the write destination word line WL (ST11). This processing is executed based on the fact that the write throttling selector 112 receives the address information on the write destination word line WL from the write control unit 111.

Next, the write throttling selector 112 selects the weight setting corresponding to the confirmed word line group WLG based on the WLG—weight conversion table 114 (ST12). The weight setting selected in this processing is transferred to the write control unit 111.

Next, the write control unit 111 executes a throttling request with the selected weight setting (ST13). The throttling request corresponds to limiting execution of a reserved write operation based on a maximum value of a sum of command weights.

Thereafter, the write control unit 111 executes the write operation at an appropriate timing (ST14). The write operation executed by the memory controller 10 includes transferring a command and write data to the memory device MD and detecting the end of the write operation of the memory device MD. The write operation executed in the memory device MD is started based on reception of the command and write data from the memory controller 10, and includes execution of a set of the program operation and the verify operation a plurality of times. Upon ending the write operation, the memory controller 10 ends a series of processing in FIG. 9 (end).

### <1-3> Effects of First Embodiment

According to the memory system 1 according to the first embodiment described above, the reliability and performance of the memory system 1 can be improved. Hereinafter, details of the present effect will be described. The write performance of the flash memory varies depending on various conditions. Examples of the fluctuation factor of the write performance include the position (address) of the write destination word line WL, the number of write/erase cycles of the block BLK, and a chip temperature of the flash memory having the write destination word line WL. Due to such factors, the write time tProg required for the write operation of the flash memory, that is, the write energy may fluctuate. For example, the write energy increases in a case where the write time tProg is slow (the write performance is poor), and the write energy decreases in a case where the write time tProg is fast (the write performance is good).

Then, the power throttling design, that is, the design of the number of chips that execute the write operation in parallel (hereinafter, referred to as a parallel write number) is performed on the premise that the write operation is performed under the worst condition of the write energy in order to realize the PLP function. In this case, since the number of parallel writes is unnecessarily reduced at the timing at a time when writing is not performed under the condition of the worst write energy, this may cause a decrease in the performance of the memory system 1.

Therefore, the memory system 1 according to the first embodiment changes the power throttling setting according to the write energy based on the information on the write destination. Specifically, as a result of changing the power throttling setting, the memory system 1 is configured to increase the number of parallel writes in a case where the write energy at the write destination is low, and to decrease the number of parallel writes in a case where the write energy at the write destination is high. More specifically, the memory system 1 according to the first embodiment changes the weight of the command according to the position (address, number, etc.) of the word line WL as the write destination to change the number of write parallel chips. In the memory system 1 according to the first embodiment, a command weight is allocated to each word line group WLG configured by a plurality of word lines WL having similar write characteristics.

As a result, the memory system 1 according to the first embodiment can use a suitable power throttling setting based on the word line dependency of the write time tProg (write energy) as illustrated in FIG. 6. As a result, the memory system 1 according to the first embodiment can maintain a suitable number of parallel writes. In addition, completion of the PLP operation at the time of power-off is ensured, and loss of write data can be avoided. Therefore, the memory system 1 according to the first embodiment can improve the reliability and performance of the memory system 1.

Note that, in the memory system 1 according to the first embodiment, it can be confirmed based on the number of write parallel chips that the weight of the command associated with the write operation has been changed. That is, it can be detected that the power throttling setting is indirectly changed by measuring the number of write parallel chips. The number of write parallel chips can be analogized based on the sequential write performance, for example, in a case where the performance value (tProg) of the flash memory and the coding rate of the ECC are known. Furthermore, whether the operation of the memory system 1 according to the first embodiment is used can be detected by observing whether the number of write parallel chips changes according to the word line WL as a write destination.

The operation of changing the weight of the command for each word line group WLG described in the first embodiment is more effective as the variation in the write performance is larger in the NAND string NS. For example, in a case where a structure corresponding to a plurality of memory cell transistors MT is formed by a plurality of hole processes, the word line group WLG is preferably finely classified. That is, the effect of improving the performance of the memory system 1 is particularly effective in a case where the command weight change according to the word line group WLG described in the first embodiment is applied to the memory device MD including the plurality of memory cell transistors MT formed by a plurality of hole processes.

### <2> Second Embodiment

A memory system 1 according to a second embodiment changes a power throttling setting described in the first embodiment based on the number of writes/erases of the write destination. The memory system 1 according to the second embodiment includes a memory controller 10a instead of the memory controller 10. Hereinafter, a difference of the memory system 1 according to the second embodiment from that of the first embodiment will be mainly described.

### <2-1> Configuration

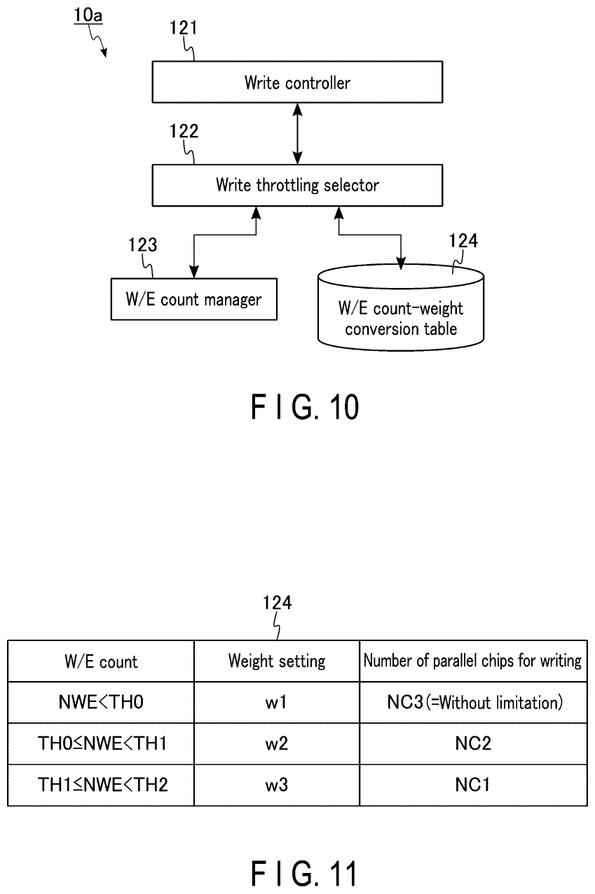

FIG. 10 is a block diagram illustrating an example of a functional configuration of the memory controller 10a according to the second embodiment. As illustrated in FIG. 10, the memory controller 10a includes, for example, a write control unit 121, a write throttling selector 122, a write/erase count (W/E count) management unit 123, and a W/E count—weight (credit) conversion table 124.

The write control unit 121 is a functional block that executes processing related to the write operation. In a case where the memory controller 10a receives a write command and write data from the host device 2, the write control unit 121 executes processing related to a write operation and power throttling setting in the write operation. For example, in the power throttling setting, the write control unit 121 inquires of the write throttling selector 122 about the weight setting corresponding to the write command to be executed. Then, the write control unit 121 reserves execution of the write operation using the weight setting received from the write throttling selector 122. As described above, the write control unit 121 can apply different weight settings for each received write command. Then, the write control unit 121 starts the reserved write operation at an appropriate timing according to the total weight of a command being executed.

The write throttling selector 122 is a functional block that manages a weight setting set for each write destination block BLK, and can obtain an appropriate power throttling setting according to the write destination block BLK. For example, upon receiving an inquiry from the write control unit 121, the write throttling selector 122 first acquires the W/E count in the block BLK to be written from the W/E count management unit 123. The W/E count management unit 123 stores and manages the number of times of execution of one cycle (set) of the write operation and the erase operation for each block BLK. Then, the write throttling selector 122 acquires the weight setting corresponding to the acquired information on the W/E counts using the W/E count—weight conversion table 124. The W/E count—weight conversion table 124 is data that defines power throttling settings according to the W/E count. Thereafter, the write throttling selector 122 transfers the acquired weight setting to the write control unit 121. (Configuration of write/erase count-weight conversion table 124)

FIG. 11 is a diagram illustrating an example of a write/erase count (W/E count)—weight conversion table 124 included in the memory controller 10a according to the second embodiment. As illustrated in FIG. 11, the W/E count—weight conversion table 124 stores information in which the W/E count and the weight setting are associated with each other. In the example shown in FIG. 11, the number of write parallel chips is also shown as the number of parallel chips for writing.

In this example, a case where the W/E count NWE is less than a threshold TH0 (NWE<TH0) is associated with the weight setting w1. A case where the W/E count NWE is equal to or greater than the threshold TH0 and less than a threshold TH1 (TH0≤NWE<TH1) is associated with the weight setting w2. A case where the W/E count NWE is equal to or greater than the threshold TH1 and less than a threshold TH2 (TH1≤NWE<TH2) is associated with the weight setting w3. The relationship between the magnitudes of the weight settings is w1<w2<w3 as in the first embodiment. In this case, the numbers of write parallel chips in “NWE<TH0”, “TH0≤NWE<TH1”, and “TH1≤NWE<TH2” are NC3, NC2, and NC1, respectively. Similarly to the first embodiment, a relationship of the number of write parallel chips is NC1<NC2<NC3. That is, in the second embodiment, a smaller weight setting is applied to the write target block BLK as the W/E count is smaller. That is, the smaller the W/E count of the write target block BLK, the larger the number of write parallel chips. As described above, in the memory system 1 according to the second embodiment, the W/E count and the write energy are associated with each other, and the power throttling setting according to the W/E count is performed.

### <2-2> Operation

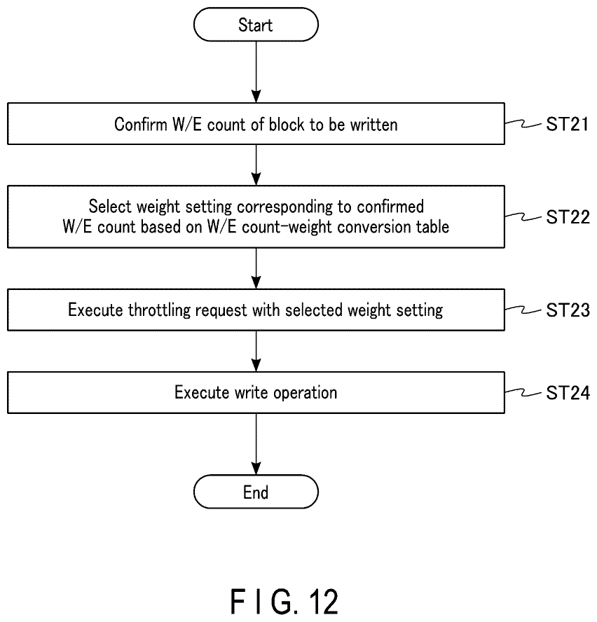

FIG. 12 is a flowchart illustrating an example of the operation of the memory controller 10a according to the second embodiment. Hereinafter, the operation of the memory controller 10a in the write operation of the memory system 1 according to the second embodiment will be described with reference to FIG. 12. In a case of receiving a write command and write data from the host device 2, the memory controller 10a starts a series of processing of FIG. 12 (start).

First, the memory controller 10a confirms the W/E count of the write destination block BLK (ST21). This processing is executed based on the fact that the write throttling selector 122 receives the address information on the block BLK of the write destination from the write control unit 121. Information on the W/E count of the write destination block BLK is acquired by the W/E count management unit 123. Next, the write throttling selector 122 selects the weight setting corresponding to the confirmed W/E count based on the W/E count—weight conversion table 124 (ST22). The weight setting selected in this processing is transferred to the write control unit 121. Next, the write control unit 121 executes a throttling request with the selected weight setting (ST23). Thereafter, the write control unit 121 executes the write operation at an appropriate timing (ST24). Upon ending the write operation, the memory controller 10a ends a series of processing in FIG. 12 (end).

### <2-3> Effects of Second Embodiment

The memory system 1 according to the second embodiment changes the power throttling setting according to the W/E count associated with the write energy. Specifically, the memory system 1 according to the second embodiment changes the weight of the command according to the W/E count of the write destination block BLK to change the number of write parallel chips.

As a result, the memory system 1 according to the second embodiment can use a more suitable power throttling setting for each block BLK of the write destination, and can maintain a suitable number of parallel writes. In addition, completion of the PLP operation at the time of power-off is ensured, and loss of write data can be avoided. Therefore, the memory system 1 according to the second embodiment can improve reliability and performance of the memory system 1 similarly to the first embodiment.

Whether the operation of the memory system 1 according to the second embodiment is used can be detected by observing whether the number of write parallel chips changes according to the W/E count of the write destination block BLK.

### <3> Third Embodiment

A memory system 1 according to a third embodiment changes a power throttling setting described in the first embodiment based on a chip temperature of a write destination. The memory system 1 according to the third embodiment includes a memory controller 10b instead of the memory controller 10. Hereinafter, differences of the memory system 1 according to the third embodiment from that of the first and second embodiments will be mainly described.

### <3-1>Configuration

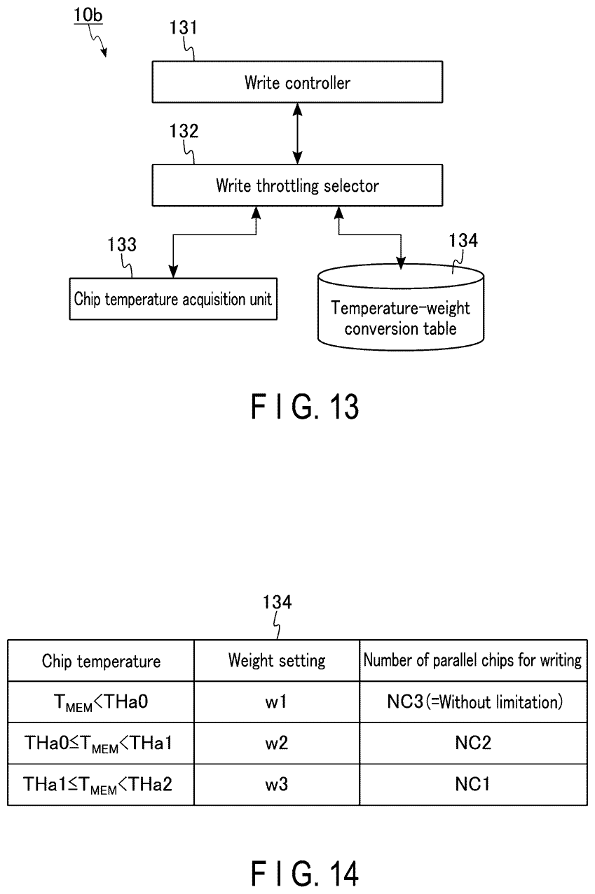

FIG. 13 is a block diagram illustrating an example of a functional configuration of the memory controller 10b according to the third embodiment. As illustrated in FIG. 13, the memory controller 10b includes, for example, a write control unit 131, a write throttling selector 132, a chip temperature acquisition unit 133, and a temperature weight (credit) conversion table 134.

The write control unit 131 is a functional block that executes processing related to the write operation. In a case where the memory controller 10b receives a write command and write data from the host device 2, the write control unit 131 executes processing related to a write operation and power throttling setting in the write operation. For example, in the power throttling setting, the write control unit 131 inquires of the write throttling selector 132 about the weight setting corresponding to the write command to be executed. Then, the write control unit 131 reserves execution of the write operation using the weight setting received from the write throttling selector 132. As described above, the write control unit 131 can apply different weight settings for each received write command. Then, the write control unit 131 starts the reserved write operation at an appropriate timing according to the total weight of a command being executed.

The write throttling selector 132 is a functional block that manages a weight setting set according to the chip temperature of the memory device MD, and can obtain an appropriate power throttling setting according to the chip temperature of the memory device MD of a write destination. For example, upon receiving an inquiry from the write control unit 131, the write throttling selector 132 first acquires the chip temperature in the memory device MD to be written from the chip temperature acquisition unit 133. The chip temperature acquisition unit 133 is configured to be able to acquire the chip temperature from each memory device MD. Note that the chip temperature acquisition unit 133 may acquire, as the chip temperature, a numerical value of a thermometer (temperature measurement circuit) included in the memory device MD from the memory device MD, or may use a numerical value of a thermometer (temperature measurement circuit) provided in the vicinity of the memory device MD. Then, the write throttling selector 132 acquires the weight setting corresponding to the acquired information on the chip temperature using the temperature—weight conversion table 134. The temperature—weight conversion table 134 is data that defines power throttling settings according to the chip temperature. Thereafter, the write throttling selector 132 transfers the acquired weight setting to the write control unit 131.

### Configuration of Temperature—Weight Conversion Table 134

FIG. 14 is a diagram illustrating an example of a temperature—weight conversion table 134 included in the memory controller 10b according to the third embodiment. As illustrated in FIG. 14, the temperature—weight conversion table 134 stores information in which the chip temperature and the weight setting are associated with each other. In the example shown in FIG. 14, the number of write parallel chips is also shown as the number of parallel chips for writing.

In this example, a case where the chip temperature T_{MEM} is less than a threshold THa0 (T_{MEM}<THa0) is associated with the weight setting w1. A case where the chip temperature T_{MEM} is equal to or higher than the threshold THa0 and lower than a threshold THa1 (THa0≤T_{MEM}<THa1) is associated with the weight setting w2. A case where the chip temperature T_{MEM} is equal to or higher than the threshold THa1 and lower than the threshold THa2 (THa1 ≤T_{MEM}<THa2) is associated with the weight setting w3. The relationship between the magnitudes of the weight settings is w1<w2<w3 as in the first embodiment. In this case, the numbers of write parallel chips at “chip temperature T_{MEM}<THa0”, “THa0≤chip temperature T_{MEM}<THa1”, and “THa1≤chip temperature T_{MEM}<THa2” are NC3, NC2, and NC1, respectively. Similarly to the first embodiment, a relationship of the number of write parallel chips is NC1<NC2<NC3. That is, in the third embodiment, a smaller weight setting is applied to the memory device MD as a write target as the chip temperature is lower. That is, the lower the chip temperature of the memory device MD of a write target, the larger the number of write parallel chips. As described above, in the memory system 1 according to the third embodiment, the chip temperature and the write energy are associated with each other, and the power throttling setting according to the chip temperature is implemented.

### <3-2> Operation

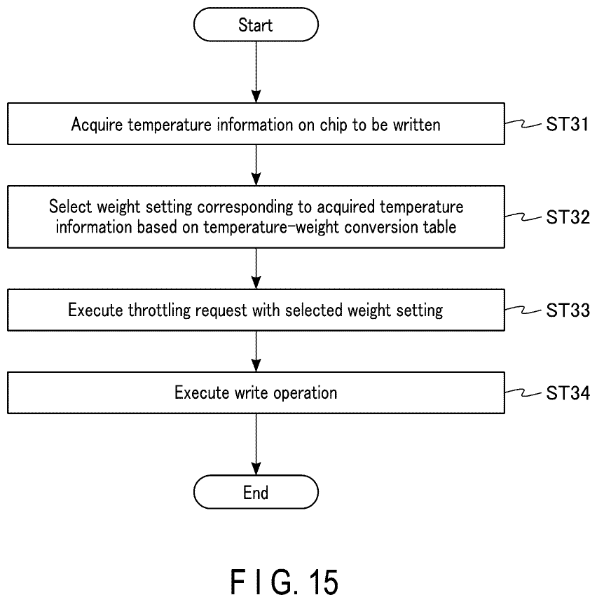

FIG. 15 is a flowchart illustrating an example of the operation of the memory controller 10b according to the third embodiment. Hereinafter, the operation of the memory controller 10b in the write operation of the memory system 1 according to the third embodiment will be described with reference to FIG. 15. In a case of receiving a write command and write data from the host device 2, the memory controller 10b starts a series of processing of FIG. 15 (start).

First, the memory controller 10b acquires temperature information on the chip (memory device MD) of a write destination (ST31). This processing is executed based on the fact that the write throttling selector 132 receives the information on the chip (memory device MD) of the write destination from the write control unit 131. The chip temperature of the memory device MD of a write destination is acquired by the chip temperature acquisition unit 133. Next, the write throttling selector 132 selects the weight setting corresponding to the confirmed chip temperature based on the temperature—weight conversion table 134 (ST32). The weight setting selected in this processing is transferred to the write control unit 131. Next, the write control unit 131 executes a throttling request with the selected weight setting (ST33). Thereafter, the write control unit 131 executes the write operation at an appropriate timing (ST34). Upon ending the write operation, the memory controller 10b ends the series of processing in FIG. 15 (end).

### <3-3> Effects of Third Embodiment

The memory system 1 according to the third embodiment changes the power throttling setting according to the chip temperature associated with the write energy. Specifically, the memory system 1 according to the third embodiment changes the weight of the command according to the chip temperature of the memory device MD of the write destination, thereby changing the number of write parallel chips.

As a result, the memory system 1 according to the third embodiment can use a more suitable power throttling setting for each memory device MD of a write destination, and can maintain a suitable number of parallel writes. In addition, completion of the PLP operation at the time of power-off is ensured, and loss of write data can be avoided. Therefore, the memory system 1 according to the third embodiment can improve reliability and performance of the memory system 1 similarly to the first embodiment.

Whether the operation of the memory system 1 according to the third embodiment is used can be detected by the memory controller 10 acquiring information on the chip temperature before the write operation and observing whether the number of write parallel chips changes according to the chip temperature of the memory device MD of a write destination.

### <4> Fourth Embodiment

A memory system 1 according to a fourth embodiment changes a power throttling setting described in the first embodiment based on a past write time tProg of a write destination word line WL. The memory system 1 according to the fourth embodiment includes a memory controller 10c instead of the memory controller 10. Hereinafter, differences of the memory system 1 according to the fourth embodiment from that of the first to third embodiments will be mainly described.

### <4-1> Configuration

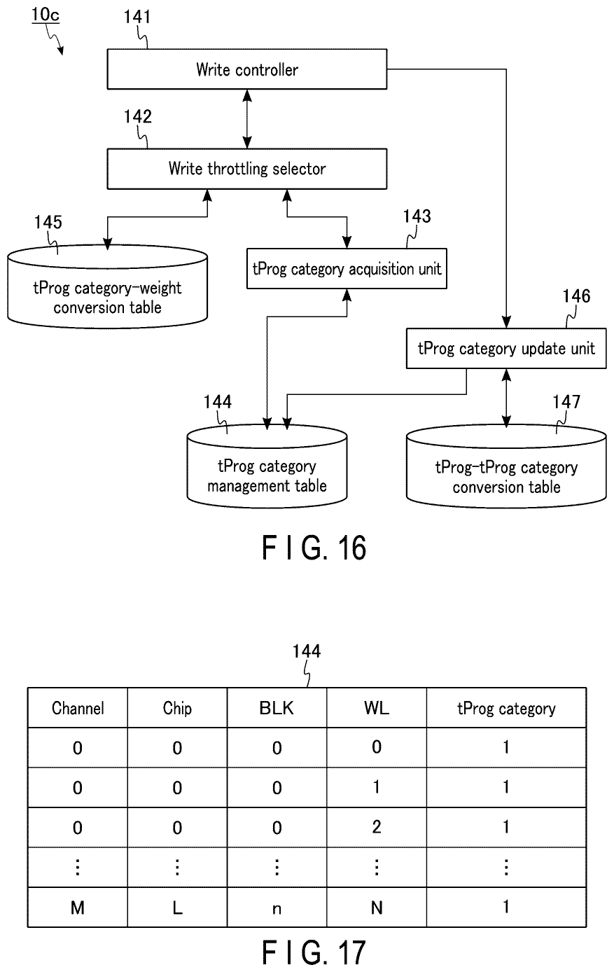

FIG. 16 is a block diagram illustrating an example of a functional configuration of a memory controller 10c according to the fourth embodiment. As illustrated in FIG. 16, the memory controller 10c includes, for example, a write control unit 141, a write throttling selector 142, a write time (tProg) category acquisition unit 143, a tProg category management table 144, a tProg category—weight conversion table 145, a tProg category update unit 146, and a tProg—tProg category conversion table 147.

The write control unit 141 is a functional block that executes processing related to the write operation. In a case where the memory controller 10c receives a write command and write data from the host device 2, the write control unit 141 executes processing related to a write operation and power throttling setting in the write operation. For example, in the power throttling setting, the write control unit 141 inquires of the write throttling selector 142 about the weight setting corresponding to the write command to be executed. Then, the write control unit 141 reserves execution of the write operation using the weight setting received from the write throttling selector 142. As described above, the write control unit 141 can apply different weight settings for each received write command. Then, the write control unit 141 starts the reserved write operation at an appropriate timing according to the total weight of a command being executed.

The write throttling selector 142 is a functional block that manages the weight setting set for each tProg category, and can obtain an appropriate power throttling setting according to the tProg category. The tProg category is information classified based on the write time tProg in the past (for example, the previous) write operation of the write destination word line WL. For example, upon receiving an inquiry from the write control unit 141, the write throttling selector 142 first acquires the tProg category in the word line WL to be written from the tProg category acquisition unit 143. Upon receiving the information on the word line WL to be written from the write throttling selector 142, the tProg category acquisition unit 143 acquires the tProg category in the word line WL using the tProg category management table 144. The tProg category management table 144 stores and manages the tProg category set according to the past write time tProg for each of the channel CH, the chip (memory device MD), the block BLK, and the word line WL. Then, the write throttling selector 142 acquires the weight setting corresponding to the acquired information on the tProg category using the tProg category—weight conversion table 145. The tProg category—weight conversion table 145 is data that defines power throttling settings according to the tProg category. Thereafter, the write throttling selector 142 transfers the acquired weight setting to the write control unit 141.

The tProg category update unit 146 is a functional block that updates the content of the tProg category management table 144 according to the write time tProg of the executed write operation. The tProg category update unit 146 uses the tProg—tProg category conversion table 147 to update the tProg category management table 144. The tProg—tProg category conversion table 147 is data that defines the tProg category according to the write time tProg. That is, the tProg—tProg category conversion table 147 is data for converting the write time tProg into the tProg category.

### 1: Configuration of Write Time Category Management Table 144

FIG. 17 is a diagram illustrating an example of a write time (tProg) category management table 144 included in the memory controller 10c according to the fourth embodiment. As illustrated in FIG. 17, the tProg category management table 144 stores information in which addresses (numbers) of the channel CH, the chip (memory device MD), the block BLK, and the word line WL are associated with the tProg category. In this example, the channel CH0, the memory device MD0, the block BLK0, and the word line WL0 are associated with the tProg category “1”. In this example, the larger the number of the tProg category is, the longer the write time is. In the memory system 1 according to the fourth embodiment, the tProg category may be managed not in units of word lines WL but in units of word line groups WLG of the first embodiment.

### 2: Configuration of Write Time Category—Weight Conversion Table 145

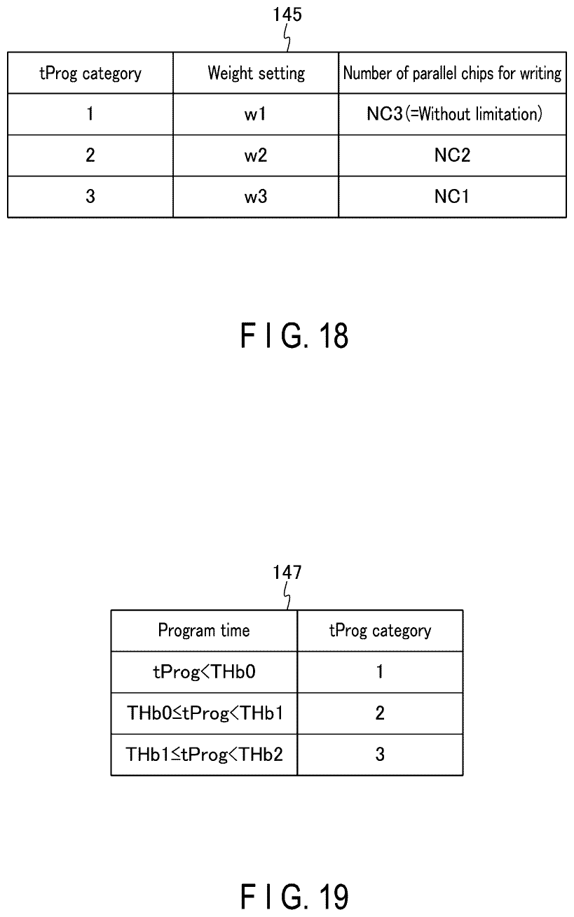

FIG. 18 is a diagram illustrating an example of a write time (tProg) category—weight conversion table 145 included in a memory controller 10c according to the fourth embodiment. As illustrated in FIG. 18, the tProg category—weight conversion table 114 stores information in which a tProg category and a weight setting are associated with each other. In the example shown in FIG. 18, the number of write parallel chips is also shown as the number of parallel chips for writing.

In this example, the past write time tProg of the tProg categories “1” to “3” is the shortest in the tProg category “1” and the longest in the tProg category “3”. In this case, weight settings w1, w2, and w3 are associated with tProg categories “1” to “3”, respectively. The relationship between the magnitudes of the weight settings is w1<w2<w3 as in the first embodiment. In addition, the numbers of write parallel chips in the tProg categories “1” to “3” are NC3, NC2, and NC1, respectively. Similarly to the first embodiment, a relationship of the number of write parallel chips is NC1<NC2<NC3. That is, in the fourth embodiment, a smaller weight setting is applied to the write target word line WL as the past write time tProg is shorter. That is, the shorter the past write time tProg of the write target word line WL, the larger the number of write parallel chips. As described above, in the memory system 1 according to the fourth embodiment, the tProg category and the write energy are associated with each other, and the power throttling setting according to the tProg category is implemented.

### 3: Configuration of Write Time—Write Time Category Conversion Table 147

FIG. 19 is a diagram illustrating an example of a write time (tProg)—write time (tProg) category conversion table 147 included in the memory controller 10c according to the fourth embodiment. As illustrated in FIG. 19, the tProg—tProg category conversion table 147 stores information in which the write time tProg and the tProg category are associated with each other.

In this example, a case where the write time tProg is less than the threshold THb0 (tProg<THb0) is associated with the tProg category “1”. A case where the write time tProg is equal to or more than the threshold THb0 and less than the threshold THb1 (THb0≤tProg<THb1) is associated with the tProg category “2”. A case where the write time tProg is equal to or more than the threshold THb1 and less than the threshold THb2 (THb1≤tProg<THb2) is associated with the tProg category “3”. Note that the tProg category may be classified into two types or four or more types.

### <4-2> Operation

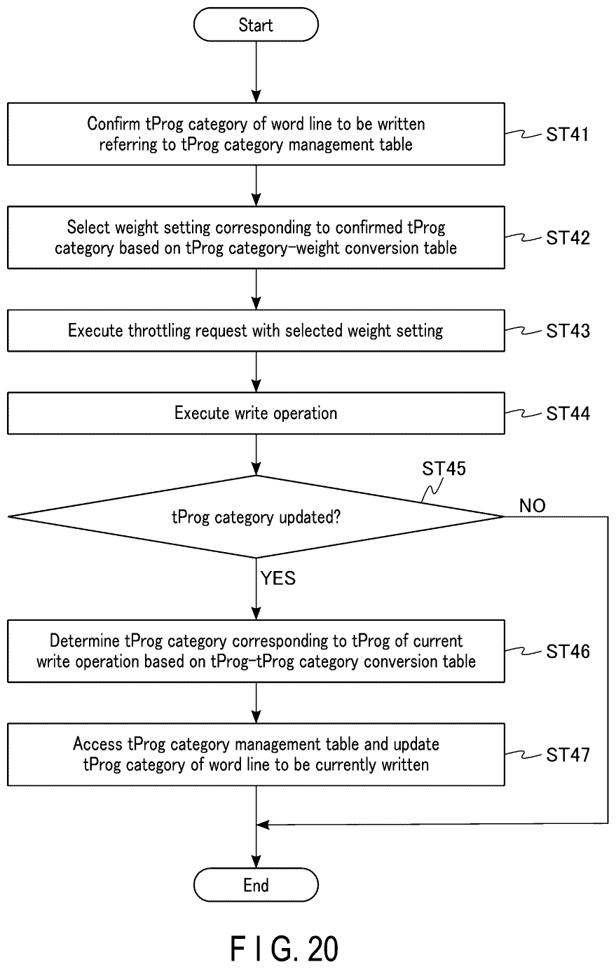

FIG. 20 is a flowchart illustrating an example of the operation of the memory controller 10c according to the fourth embodiment. Hereinafter, the operation of the memory controller 10c in the write operation of the memory system 1 according to the fourth embodiment will be described with reference to FIG. 20. In a case of receiving a write command and write data from the host device 2, the memory controller 10c starts a series of processing of FIG. 20 (start).

First, the memory controller 10c refers to the tProg category management table 144 to confirm the tProg category of the write destination word line WL (ST41). This processing is executed based on the fact that the write throttling selector 142 receives the information on the channel CH, the chip (memory device MD), the block BLK, and the word line WL of the write destination from the write control unit 141. The tProg category of the write destination word line WL is acquired by the tProg category acquisition unit 143. Next, the write throttling selector 142 selects the weight setting corresponding to the confirmed tProg category based on the tProg category weight conversion table 145 (ST42). The weight setting selected in this processing is transferred to the write control unit 141. Next, the write control unit 141 executes a throttling request with the selected weight setting (ST43). Thereafter, the write control unit 141 executes the write operation at an appropriate timing (ST44). Upon ending the write operation, the memory controller 10c confirms whether to update the tProg category (ST45).

In the processing of ST45, the write control unit 141 may determine whether to update the tProg category based on the write time tProg of the current write operation, based on whether the W/E count of the block BLK to be written exceeds a predetermined count, or based on the use time of the memory device MD. The present invention is not limited thereto, and the tProg category may be updated every time, and a condition for updating the tProg category may be freely set. In a case where the tProg category is not updated (ST45: NO), the memory controller 10c ends the series of processing in FIG. 20 (end).

In a case of updating the tProg category (ST45: YES), the tProg category update unit 146 determines the tProg category corresponding to the write time tProg of the current write operation based on the tProg—tProg category conversion table 147 (ST46). This processing is executed based on the fact that the tProg category update unit 146 receives an update instruction of the tProg category management table 144 and information on the write time tProg of the current write operation from the write control unit 141. Thereafter, the tProg category update unit 146 accesses the tProg category management table 144 and updates the tProg category of the current write target word line WL (ST47). Upon ending the processing of ST47, the memory controller 10c ends the series of processing of FIG. 20 (end).

Note that a method by which the memory controller 10c acquires the write time tProg is freely. For example, the memory controller 10c may detect a period (time) from the start to the end of the write operation of the memory device MD based on the ready/busy signal RBn, and count the length of the period with a timer. In addition, the memory controller 10c may confirm whether the write operation of the memory device MD is completed by periodically transmitting polling (for example, a status read command) after transmitting the command of the write operation to the memory device MD.

<4-3> Effects of fourth Embodiment

The memory system 1 according to the fourth embodiment changes the power throttling setting according to the write time (tProg category) associated with the write energy. Specifically, the memory system 1 according to the fourth embodiment changes the weight of the command based on the past (for example, the previous) write time tProg of the write destination word line WL to change the number of write parallel chips. Then, in the memory system 1 according to the fourth embodiment, the command weight is allocated for each tProg category having similar write characteristics.

As a result, the memory system 1 according to the fourth embodiment can use a more suitable power throttling setting for each word line WL of a write destination, and can maintain a suitable number of parallel writes. In addition, completion of the PLP operation at the time of power-off is ensured, and loss of write data can be avoided. Therefore, the memory system 1 according to the fourth embodiment can improve reliability and performance of the memory system 1 similarly to the first embodiment.

Whether the operation of the memory system 1 according to the fourth embodiment is used can be detected by observing whether the number of write parallel chips changes according to the write time tProg of the write destination word line WL.

### <5> Others

The memory system 1 described above can be variously modified.

In each of the memory controller 10, 10a, 10b, and 10c of the plurality of embodiments, a micro processing unit (MPU) may be used instead of the CPU 13. In addition, each of the processing described in the above embodiments may be executed by a dedicated hardware circuit, a processor that executes a program (firmware), or a combination thereof. In the present specification, “connection” indicates electrical connection, and does not exclude that another element is interposed therebetween. “Electrically connected” may be via an insulator as long as it can operate in the same manner as electrically connected.

In the plurality of embodiments described above, each of the circuit configuration, the planar layout, and the cross-sectional structure of the memory device MD can be appropriately changed. For example, the memory device MD includes memory pillars that each penetrate (pass through) a plurality of conductive layers that function as word lines WL. The memory pillar functions, for example, as a part of one NAND string NS. The conductive layer functioning as the select gate line SGS or SGD may be provided as a single layer or a plurality of layers. The number of wiring layers and contact plugs included in the memory device MD can be appropriately changed according to the circuit design. The cross-sectional structure of the memory pillar may be circular or elliptical. The semiconductor film of the memory pillar and the source line (semiconductor layer) may be electrically connected via a bottom portion of the memory pillar, or may be electrically connected via a side surface of the memory pillar. The memory device MD may have a structure in which a chip on which the memory cell array 21 is provided and a chip on which a circuit or the like other than the memory cell array 21 is provided are bonded together.

In the plurality of embodiments, the structure corresponding to the memory pillar may be formed using one hole process. In a case where the structure corresponding to the memory pillar is formed using two hole processes, the memory pillar includes a lower memory pillar and an upper memory pillar connected in the stacking direction of the plurality of conductive layers. Each of the lower memory pillar and the upper memory pillar may be referred to as a sub-pillar of the memory pillar. Each sub-pillar may have a straight shape provided with a constant diameter, a reverse tapered shape in which the diameter (cross-sectional area) of the lower end is larger than the diameter (cross-sectional area) of the upper end, or a bowing shape in which the diameter (cross-sectional area) of the intermediate portion is maximized. The hole process for forming the structure corresponding to the memory pillar may be performed three or more times. That is, the memory pillar may include three or more sub-pillars.

Hereinafter, other embodiments will be additionally described.

### Supplementary Note 1

A memory system, comprising:
a plurality of memory devices; and
a memory controller configured to control the memory devices, wherein
the memory controller is configured to:
receive a data write command to any of the memory devices from an external host device; and
change a power throttling setting based on information on a write destination designated by the received write command,
as a result of changing the power throttling setting,
in a case where a write energy at the write destination is a first value, the number of write operations that can be executed in parallel is a first number, and
in a case where the write energy at the write destination is a second value lower than the first value, the number of write operations that can be executed in parallel is a second number larger than the first number.

### Supplementary Note 2

The memory system according to Supplementary Note 1, wherein
each of the memory devices includes a plurality of blocks,
each of the blocks include a plurality of memory cell transistors and a plurality of word lines connected to a plurality of corresponding first memory cell transistors among the memory cell transistors, and
as the information, an address of a word line of a write destination is used.

### Supplementary Note 3

The memory system according to Supplementary Note 2, wherein
the word lines are classified into a plurality of groups to which the power throttling settings different from each other are allocated. cl Supplementary Note 4

The memory system according to Supplementary Note 3, further comprising a storage circuit configured to store the power throttling setting for each of the plurality of groups.

### Supplementary Note 5

The memory system according to Supplementary Note 3, wherein each of the plurality of memory devices includes a plurality of conductive layers arranged in a first direction and a pillar provided to penetrate the plurality of conductive layers in the first direction, wherein the conductive layers function as the word lines, and a plurality of intersections between the plurality of conductive layers and the pillar function as the memory cell transistors.

### Supplementary Note 6

The memory system according to Supplementary Note 5, wherein
the conductive layers are arranged across a first tier and a second tier, the pillar has a structure in which a first sub-pillar included in the first tier and a second sub-pillar included in the second tier are connected in the first direction, and the memory controller is further configured to apply different power throttling settings in a case where a word line corresponding to a first conductive layer included in the first tier among the conductive layers is a write target and in a case where a word line corresponding to a second conductive layer included in the second tier among the conductive layers is the write target.

### Supplementary Note 7

The memory system according to Supplementary Note 1, wherein
each of the memory devices includes a plurality of blocks,
each of the blocks include a plurality of memory cell transistors and a plurality of word lines connected to a plurality of corresponding first memory cell transistors among the memory cell transistors, and
as the information, information on a write time of the write operation executed last time in the word line of the write destination is used.

### Supplementary Note 8

The memory system according to Supplementary Note 7, further comprising a storage circuit configured to store information related to write times for each of the plurality of word lines.

### Supplementary Note 9

The memory system according to Supplementary Note 7, further comprising a storage circuit configured to store the power throttling setting for each of a plurality of conditions of the write time.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system, comprising:
a plurality of memory devices; and
a memory controller configured to control the memory devices, wherein
the memory controller is configured to:
receive a data write command to any of the memory devices from an external host device; and
change a power throttling setting based on information on a write destination designated by the received write command,
as a result of changing the power throttling setting,
in a case where a write energy at the write destination is a first value, the number of write operations that can be executed in parallel is a first number, and
in a case where the write energy at the write destination is a second value lower than the first value, the number of write operations that can be executed in parallel is a second number larger than the first number.

2. The memory system according to claim 1, wherein
each of the memory devices includes a plurality of blocks,
each of the blocks include a plurality of memory cell transistors and a plurality of word lines connected to a plurality of corresponding first memory cell transistors among the memory cell transistors, and
as the information, an address of a word line of a write destination is used.

3. The memory system according to claim 2, wherein
the word lines are classified into a plurality of groups to which the power throttling settings different from each other are allocated.

4. The memory system according to claim 1, wherein
each of the memory devices includes a plurality of blocks,
each of the blocks include a plurality of memory cell transistors and a plurality of word lines connected to a plurality of corresponding first memory cell transistors among the memory cell transistors, and
as the information, the number of times a pair of the write operation and the erase operation in a block of the write destination has been executed is used.

5. The memory system according to claim 4, further comprising a storage circuit configured to store the power throttling setting for each of a plurality of conditions regarding the number of times the set of the write operation and the erase operation has been executed.

6. The memory system according to claim 1, wherein
as the information, a chip temperature of the memory device of the write destination is used.

7. The memory system according to claim 6, further comprising a storage circuit configured to store the power throttling setting for each of a plurality of conditions of the chip temperature of the memory device.

8. The memory system according to claim 1, wherein
each of the memory devices includes a plurality of blocks,
each of the blocks include a plurality of memory cell transistors and a plurality of word lines connected to a plurality of corresponding first memory cell transistors among the memory cell transistors, and
as the information, information on a write time of the write operation executed last time in the word line of the write destination is used.

9. The memory system according to claim 8, wherein
in a case where the write time is a first time, the number of write operations that can be executed in parallel is the first number, and
in a case where the write time is a second time shorter than the first time, the number of write operations that can be executed in parallel is the second number.

10. The memory system according to claim 8, further comprising a storage circuit configured to store information on the write time for each of the word lines.

11. A method for controlling a memory system including a plurality of memory devices, the method comprising:
receiving a data write command to any of the memory devices from an external host device; and
changing a power throttling setting based on information on a write destination designated by the received write command, wherein
as a result of changing the power throttling setting,
in a case where a write energy at the write destination is a first value, the number of write operations that can be executed in parallel is a first number, and
in a case where the write energy at the write destination is a second value lower than the first value, the number of write operations that can be executed in parallel is a second number larger than the first number.

12. The control method according to claim 11, wherein
each of the memory devices includes a plurality of blocks,
each of the blocks include a plurality of memory cell transistors and a plurality of word lines connected to a plurality of corresponding first memory cell transistors among the memory cell transistors, and
as the information, an address of a word line of a write destination is used.

13. The control method according to claim 12, wherein
the word lines are classified into a plurality of groups to which the power throttling settings different from each other are allocated.

14. The control method according to claim 11, wherein
each of the memory devices includes a plurality of blocks,
each of the blocks include a plurality of memory cell transistors and a plurality of word lines connected to a plurality of corresponding first memory cell transistors among the memory cell transistors, and
as the information, the number of times a pair of the write operation and the erase operation in a block of the write destination has been executed is used.

15. The control method according to claim 14, further comprising storing the power throttling setting for each of a plurality of conditions regarding the number of times the set of the write operation and the erase operation has been executed.

16. The control method according to claim 11, wherein
as the information, a chip temperature of the memory device of the write destination is used.

17. The control method according to claim 16, further comprising storing the power throttling setting for each of a plurality of conditions of the chip temperature of the memory device.

18. The control method according to claim 11, wherein
each of the memory devices includes a plurality of blocks,
each of the blocks include a plurality of memory cell transistors and a plurality of word lines connected to a plurality of corresponding first memory cell transistors among the memory cell transistors, and
as the information, information on a write time of the write operation executed last time in the word line of the write destination is used.

19. The control method according to claim 18, wherein
in a case where the write time is a first time, the number of write operations that can be executed in parallel is the first number, and
in a case where the write time is a second time shorter than the first time, the number of write operations that can be executed in parallel is the second number.

20. The control method according to claim 18, further comprising storing information on the write time for each of the word lines.
